(19) United States
(12) Patent Application Publication
(10) Pub. No.: US 2024/0429225 A1
(43) Pub. Date: Dec. 26, 2024

(54) ELECTROSTATIC DISCHARGE PROTECTION CIRCUIT FOR DIE-TO-DIE INPUT/OUTPUT SIGNALS

(71) Applicant: Intel Corporation, Santa Clara, CA (US)

(72) Inventors: Krzysztof Domanski, Neubiberg (DE); Robert Haeussler, Augsburg (DE)

(73) Assignee: Intel Corporation, Santa Clara, CA (US)

(21) Appl. No.: 18/212,342

(22) Filed: Jun. 21, 2023

(51) Int. Cl. H01L 27/02; H02H 9/04

(52) U.S. Cl. CPC H01L 27/0255; H02H 9/046

(57) ABSTRACT

An integrated circuit device includes an electrostatic discharge (ESD) protection circuit comprising a plurality of P+/N-well diodes (P-diodes) and a plurality of N+/P-well (N-diodes) arranged in a stripe geometry, a p-tap anode stripe of the ESD protection circuit shared between a first P-diode and a second P-diode of the ESD protection circuit, and a n-tap cathode stripe of the ESD protection circuit shared between a first N-diode and a second N-diode of the ESD protection circuit. Other examples are disclosed and claimed.

### BACKGROUND

Electrostatic discharge (ESD) can be harmful to electronics. During an ESD event, charge is transferred from one object to another (e.g., from a person to an integrated circuit (IC)). The transferred charge can result in a high current passing through the IC in a short time, potentially damaging the device. Such ESD events can affect an IC throughout the IC lifetime, including during manufacturing and assembly. Electrostatic discharge (ESD) events that may damage integrated circuits can occur during the manufacturing and assembly of semiconductor devices. An IC may incorporate on-chip ESD protection structures to protect the input, output, and power supply pins of the IC.

There is an ongoing need for improved computational devices to enable ever increasing demand for modeling complex systems, providing reduced computation times, and other considerations. In some contexts, scaling features of ICs has been a driving force for such improvements. Other advancements have been made in materials, device structure, circuit layout, and so on. In particular, there is an ongoing desire to improve ESD protection circuits that are utilized for, in, or otherwise support operation of ICs. It is with respect to these and other considerations that the present improvements have been needed. Such improvements may become critical as the desire to improve computational efficiency become even more widespread.

### BRIEF DESCRIPTION OF THE DRAWINGS

The material described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Further, where considered appropriate, reference labels have been repeated among the figures to indicate corresponding or analogous elements, e.g., with the same or similar functionality. The disclosure will be described with additional specificity and detail through use of the accompanying drawings:

FIG. 1 illustrates a block diagram of an example integrated circuit (IC) device that includes one or more shared stripe electrostatic discharge (SS ESD) protection circuits for die-to-die (D2D) input/output (IO);

FIG. 2 illustrates a schematic diagram of an example of an ESD protection circuit where various of the stripes may be shared;

FIG. 3 illustrates a block diagram of an example physical layout of an example SS ESD protection circuit;

FIG. 4 illustrates a block diagram of an example physical layout of an example SS ESD protection circuit with multi-finger diodes;

FIG. 5 illustrates a layout diagram of an IC device that includes example SS ESD protection circuits;

FIG. 6 is an enlarged view of an area A of the IC device in FIG. 5;

FIG. 7 illustrates a block diagram of a system that includes stacked IC devices with examples of SS ESD protection circuits for D2D IO;

FIG. 8 illustrates a diagram of an example data server machine employing an IC device with a SS ESD protection circuit for D2D IO; and

FIG. 9 is a block diagram of an example computing device, all in accordance with at least some implementations of the present disclosure.

### DETAILED DESCRIPTION

In the following detailed description, reference is made to the accompanying drawings that show, by way of illustration, specific examples in which the claimed subject matter may be practiced. These examples are described in sufficient detail to enable those skilled in the art to practice the subject matter. The various examples, although different, are not necessarily mutually exclusive. For example, a particular feature, structure, or characteristic described herein, in connection with one example, may be implemented within other examples without departing from the spirit and scope of the claimed subject matter.

References within this specification to “one example” or “an example” mean that a particular feature, structure, or characteristic described in connection with the example is included in at least one implementation encompassed within the present description. Therefore, the use of the phrase “one example” or “in an example” does not necessarily refer to the same example. In addition, the location or arrangement of individual elements within each disclosed example may be modified without departing from the spirit and scope of the claimed subject matter. The following detailed description is, therefore, not to be taken in a limiting sense, and the scope of the subject matter is defined only by the appended claims, appropriately interpreted, along with the full range of equivalents to which the appended claims are entitled.

The terms “over,” “to,” “between,” and “on” as used herein may refer to a relative position of one layer with respect to other layers. One layer “over” or “on” another layer or bonded “to” another layer may be directly in contact with the other layer or may have one or more intervening layers. One layer “between” layers may be directly in contact with the layers or may have one or more intervening layers.

The terms “coupled” and “connected.” along with their derivatives, may be used herein to describe structural relationships between components. These terms are not intended as synonyms for each other. Rather, in particular examples, “connected” may be used to indicate that two or more elements are in direct physical or electrical contact with each other. “Coupled” may be used to indicated that two or more elements are in either direct or indirect (with other intervening elements between them) physical or electrical contact with each other, and/or that the two or more elements co-operate or interact with each other (e.g., as in a cause an effect relationship, an electrical relationship, a functional relationship, etc.).

The term “circuit” or “module” may refer to one or more passive and/or active components that are arranged to cooperate with one another to provide a desired function. The term “signal” may refer to at least one current signal, voltage signal, magnetic signal, or data/clock signal. The meaning of “a,” “an,” and “the” include plural references. The meaning of “in” includes “in” and “on.”

The vertical orientation is in the z-direction and recitations of “top,” “bottom,” “above,” and “below” refer to relative positions in the z-dimension with the usual meaning. However, examples are not necessarily limited to the orientations or configurations illustrated in the figure. The term “aligned” (i.e., vertically or laterally) indicates at least a portion of the components are aligned in the pertinent direction while “fully aligned” indicates an entirety of the components are aligned in the pertinent direction.

The terms “substantially,” “close,” “approximately,” “near,” and “about,” generally refer to being within +/−10% of a target value (unless specifically specified). Unless otherwise specified in the specific context of use, the term “predominantly” means more than 50%, or more than half. For example, a composition that is predominantly a first constituent means more than half of the composition is the first constituent. The term “primarily” means the most, or greatest, part. For example, a composition that is primarily a first constituent means the composition has more of the first constituent than any other constituent. A composition that is primarily first and second constituents means the composition has more of the first and second constituents than any other constituent.

Unless otherwise specified, the use of the ordinal adjectives “first,” “second,” and “third,” etc., to describe a common object, merely indicate that different instances of like objects to which are being referred and are not intended to imply that the objects so described must be in a given sequence, either temporally, spatially, in ranking, or in any other manner.

For the purposes of the present disclosure, phrases “A and/or B” and “A or B” mean (A), (B), or (A and B). For the purposes of the present disclosure, the phrase “A, B, and/or C” means (A), (B), (C), (A and B), (A and C), (B and C), or (A, B and C).

Views labeled “cross-sectional,” “profile.” and “plan” correspond to orthogonal planes within a cartesian coordinate system. Thus, cross-sectional and profile views are taken in the x-z and y-z planes, and plan views are taken in the x-y plane. Typically, profile views in the x-z plane are cross-sectional views. Where appropriate, drawings are labeled with axes to indicate the orientation of the figure.

Some integrated circuits (ICs) may utilize diode-based electrostatic discharge (ESD) protection at a pad (e.g., a metallization structure associated with a signal). A pad macro may consists of separate instances of a metallized N+/P-well diode (N-diode) and a metallized P+/N-well diode (P-diode) coupled in series between a positive voltage supply (e.g., VDD) and a reference voltage (e.g., VSS or ground) with the anode of the N-diode at VSS, the cathode of the P-diode at VDD, and the pad at the junction of the cathode of the N-diode and the anode of the P-diode. Two signal pads may be arranged as two instances of such pad macros placed next to each other. A problem with the macro approach is that each diode consists of separate anode and cathode layouts and separate diode straps are utilized to enable Human-Body-Model (HBM) type of ESD stress. Under HBM the current can be forced between two neighboring pads. The current capability of diodes at both pads has to be the same. A problem is that such pad macros that support HBM-based ESD protection consume significant circuit area.

Another approach to ESD protection for signals involves arranging the ESD diodes in a ring-geometry, where diffusion at a pad is surrounded by ring of diode-strap diffusion. A problem is that a ring style of diode-strap layout causes even more area overhead, because it provides two stripes, one on the top and one on the bottom of the diode, that must be placed in spacing to other diffusions according to design-rules.

In general, circuit area on an IC is space constrained. For stacked ICs, metallization structures such as micro-bumps may be utilized to interconnect ICs in the stack. An example of micro-bumps includes small copper bumps that are formed on the die and then connected and assembled into a package to provide suitable electrical connections between two or more IC die. The micro-bumps are generally made at some specified minimum pitch or spacing between the adjacent bumps on the die (e.g., a 25 μm bump size on a minimum 40 μm pitch). As the bump size or pitch scales down, other problems may occur.

For an IC made to be utilized in a stacked arrangement, the area and pitch of die-to-die (D2D) input/output (IO) signals are arranged to be compatible with a specified micro-bump pitch. In the floor-plan of particular IC, the micro-bumps may be organized as bundles of bumps for various D2D connections (e.g., power, IO signals, other signals, etc.) including one or more bundles for D2D IO signals. The vertical and horizontal size of a bundle is a specified constraint that must fit together with a desired number of micro-bumps for pad connections available on both sides of the IC. For some ICs, the area of a single D2D IO may play a significant role in floor-planning and overall chip area. One problem is that some on-chip ESD diode layouts may lead to significant area consumption of ESD diodes within a single D2D IO. Another problem is that if the vertical size of a D2D-IO bundle is too large (e.g., due to excessive circuit area needs), then there may be more micro-bumps than needed on both sides for the IO signals (e.g., the additional floating micro-bumps may not be effectively utilized). The D2D-IO bundle layout is constrained also in the horizontal direction due to power-bus routing and neighboring circuit blocks.

Some examples may overcome one or more of the foregoing problems. Some examples may provide technology for an improved or area-optimized layout of ESD diodes for D2D IO signals. In some examples, D2D IO signals may only be exposed to Charge Device Model (CDM) stress (e.g., obviating the need to provide HBM-based ESD protection between two neighboring pads). In general, HBM stress is not present in practical applications of D2D IO signals and HBM stress is not utilized during D2D IO circuit verification. Additionally, because the D2D IO signals are not exposed to latchup risk, a ring type of diode-strap layout (e.g., cathode for P-diode or anode for N-diode) is not required for ESD diodes used in D2D IO signals (e.g., the latchup guard-rings are not needed in most practical D2D IO applications). Advantageously, an amount of circuit area utilized by the ESD protection circuit may be reduced (e.g., thereby supporting finer-pitched micro-bumps and smaller D2D-IO bundle sizes with fewer floating micro-bumps).

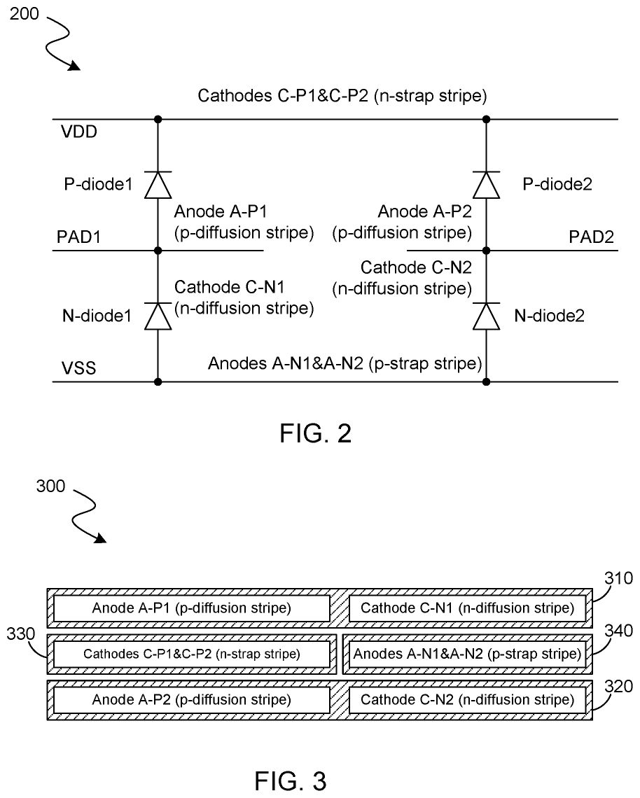

Some examples may provide technology for an area optimized layout for ESD diodes in a bundle of many D2D IOs (e.g., tens, hundreds, thousands, etc.). In some examples, the ESD diodes are laid out in a stripe geometry, where the p-tap anode stripe of two ESD P-diodes (e.g., see P-diode1 and P-diode2 in FIGS. 2-3) is shared between the two ESD P-diodes connected to two pads (e.g., see PAD1 and PAD2 in FIGS. 2-3), and the n-tap cathode stripe of two ESD N-diodes (e.g., see N-diode1 and N-diode2 in FIGS. 2-3) is shared between the two ESD N-diodes connected to the two pads (e.g., see PAD1 and PAD2 in FIGS. 2-3).

Advantageously, some examples may reduce an area of layout with a shared anode and cathode as compared to a macro pad approach or ring approach. For example, a macro pad approach may involve four stripes while some examples may utilize three stripes (e.g., an area saving of about 25%). For example, an area of layout may be reduced by up to 50% as compared to a ring geometry. Another advantage is that an area reduction of ESD in D2D IOs in some examples may lead to compatibility of D2D IO with a finer micro-bump pitch.

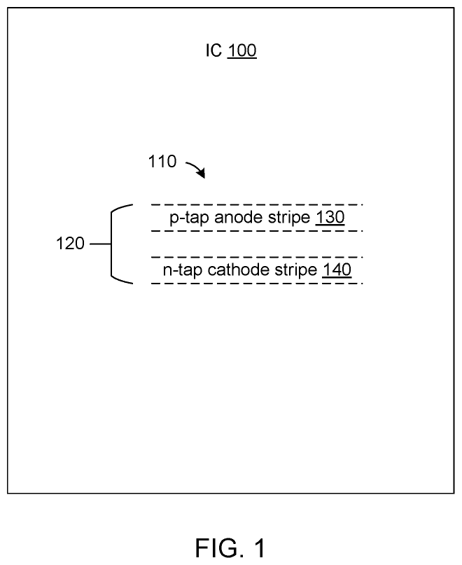

FIG. 1 shows an illustrative block diagram of an example IC device 100 that includes an ESD protection circuit 110 comprising a plurality of P-diodes (not shown) and a plurality of N-diodes (not shown) arranged in a stripe geometry 120. A p-tap anode stripe 130 of the ESD protection circuit 110 is shared between a first P-diode and a second P-diode of the ESD protection circuit 110, and a n-tap cathode stripe 140 of the ESD protection circuit 110 is shared between a first N-diode and a second N-diode of the ESD protection circuit 110. In some examples, the ESD protection circuit 110 provides protection for a signal from a static charge stored in the IC itself (e.g., sufficient protection for a CDM). For example, the ESD protection circuit 110 provides protection for the signal from a discharge voltage of between five volts and thirty five volts. In some examples, the signal comprises a D2D IO signal.

In some examples, an anode of the first P-diode and a cathode of the first N-diode may be coupled to a first pad (e.g., see PAD1 in FIGS. 2-3), and an anode of the second P-diode and a cathode of the second N-diode may be coupled to a second pad (e.g., see PAD2 in FIGS. 2-3), and the IC device 100 may further include a first strap diffusion of the first P-diode and the first N-diode at the first pad shared with a second strap diffusion of the second P-diode and the second N-diode at the second pad. In some examples, the shared first and second strap diffusions may be arranged in a one-finger layout. In some examples, the shared first and second strap diffusions may be arranged in a multi-finger layout.

FIG. 2 shows a schematic diagram of an example of an ESD protection circuit 200 where various of the stripes may be shared. The ESD protection circuit 200 includes P-diodes (P-diode1 and P-diode2) and N-diodes (N-diode1 and N-diode2). The cathode C-P1 of P-diode1 is coupled to VDD (e.g., a positive supply voltage) and the anode A-P1 of P-diode1 is coupled to PAD1. The cathode C-P2 of P-diode2 is coupled to VDD and the anode A-P2 of P-diode2 is coupled to PAD2. The cathode C-N1 of N-diode1 is coupled to PAD1 and the anode A-N1 of N-diode1 is coupled to VSS (e.g., a reference voltage or ground). The cathode C-N2 of N-diode2 is coupled to PAD2 and the anode A-N2 of N-diode2 is coupled to VSS.

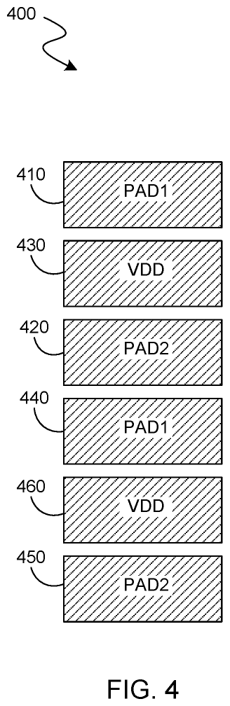

In some examples, the ESD protection circuit 200 may be utilized for a bundle of many D2D IOs with an area optimized layout for the ESD diodes. For example, a layout for the ESD diodes may be arranged as a stripe geometry where the p-tap anode stripe of N-diode1 and N-diode2 is shared between the two diodes N-diode1 and N-diode2 respectively connected to PAD1 and PAD2 (e.g., see FIG. 3), and where the n-tap cathode stripe of P-diode1 and P-diode2 is shared between the two diodes P-diode1 and P-diode2 respectively connected to PAD1 and PAD2 (see FIG. 3). In some examples, the strap diffusions of the ESD diodes at PAD1 and PAD2 can be shared (e.g., see FIG. 3), because the HBM test is not required for D2D IOs. Examples of a shared-strap diode-layout-style may be applied to one-finger diode (e.g., see FIG. 3) or multi-finger diodes (e.g., see FIG. 4).

As noted in FIG. 2, the cathode C-P1 of P-diode1 and the cathode C-P2 of P-diode2 may be coupled to VDD. The anode A-P1 of P-diode1 may be coupled to PAD1. The anode A-P2 of P-diode2 may be coupled to PAD2. The cathode C-N1 of N-diode1 may be coupled to PAD1. The cathode C-N2 of N-diode2 may be coupled to PAD2. The anode A-N1 of N-diode1 and the anode A-N2 of N-diode2 may be coupled to VSS.

FIG. 3 shows a block diagram of an example physical layout for an ESD protection circuit 300. The ESD protection circuit 300 includes a plurality of ESD diodes (not shown) including at least a first P-diode (e.g., P-diode1 from FIG. 2), a first N-diode (e.g., N-diode1 from FIG. 2), a second P-diode (e.g., P-diode2 from FIG. 2), and a second N-diode (e.g., N-diode2 from FIG. 2). For example, the first and second P-diodes and the first and second N-diodes are arranged in a stripe geometry. The ESD diodes may be fabricated with any suitable technology on one or more internal layers of an IC. The ESD protection circuit further includes a first metallization structure 310 for a first pad (e.g., PAD1 from FIG. 2) on a first layer (e.g., an outermost layer) with connections under the first metallization structure 310 on another layer (e.g., an inner layer) to an anode of the first P-diode and a cathode of the first N-diode, a second metallization structure 320 for a second pad on the first layer with connections under the second metallization structure 320 on another layer to an anode of the second P-diode and a cathode of the second N-diode, a third metallization structure 330 for a positive voltage source on the first layer between and immediately adjacent to the first and second metallization structures 310, 320 and with connections under the third metallization structure 330 on another layer to respective cathodes of the first and second P-diodes, and a fourth metallization structure 340 for a reference voltage source on the first layer aligned with the third metallization structure 330 (e.g., in a same stripe) and between and immediately adjacent to the first and second metallization structures 310, 320 and with connections under the fourth metallization structure 340 on another layer to respective anodes of the first and second N-diodes.

In some examples, the first layer may correspond to an external layer of an IC device, and/or the first and second P-diodes and the first and second N-diodes may be to provide ESD protection for a D2D IO signal. In some examples, the ESD protection circuit 300 may further comprise a multi-finger diode arrangement that includes a fifth metallization structure for the first pad on the first layer immediately adjacent to and on an opposite side of the second metallization structure 320 with respect to the third metallization structure 330, a sixth metallization structure for the second pad on the first layer, and a seventh metallization structure for the positive voltage source on the first layer between and immediately adjacent to the fifth and sixth metallization structures (e.g., see FIG. 4).

FIG. 4 shows an example layout of an ESD protection circuit 400 with a PAD and PAD2 bundle for multi-finger ESD diodes. The layout may support a shared n-diffusion stripe for P-diode1 and P-diode2. First metallization structure 410 is for PAD1, second metallization structure 420 is for PAD2, and third metallization structure 430 is for VDD. A fourth metallization structure for VSS is not shown. The multi-finger layout further includes a fifth metallization structure 440 for PAD1 immediately adjacent to and on an opposite side of the second metallization structure 420 with respect to the third metallization structure 430, a sixth metallization structure 450 for PAD2, and a seventh metallization structure 460 for VDD between and immediately adjacent to the fifth and sixth metallization structures 440, 450.

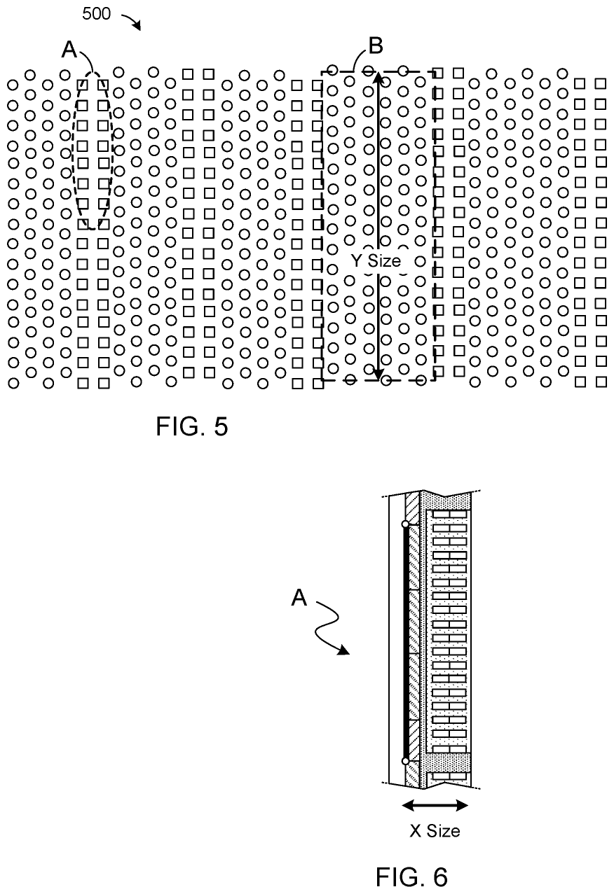

FIG. 5 is an illustrative diagram of a portion of an IC device 500 with an ESD protection circuit with shared stripes as described herein. FIG. 6 is an enlarged view of an area A of the IC device 500. In an IC device using 35 μm micro-bump-pitch (e.g., or less) several thousands of D2D IOs may be placed. With ongoing downscaling of packaging technology, the micro-bump-pitch may further and hundreds of thousands of D2D IOs may be provided on a single die. In FIG. 5, the circles represent micro-bumps and the squares represent metallization areas for power connections (e.g., VDD. VSS, etc.). The dashed line box B represents a D2D IO bundle, with the IOs stacked vertically. As the vertical size of the D2D IO bundle increases, the area for micro-bumps increases (e.g., the “Y” size for the ESD protection circuit increases as the vertical size of the D2D bundle increases). The horizontal size for the ESD protection may be fixed based on the pitch of the micro-bumps or the spacing between the metallization structures for the power connections (e.g., a fixed “X” size). Preferably, the ESD protection circuit does not increase the area of the D2D IO bundle beyond the number of needed D2D IO connections (e.g., does not increase the number of floating micro-bumps).

Some examples provide technology for area-optimized ESD protection of D2D IOs with a receiver/transmitter (RX/TX) implemented within sensitive IC devices. The D2D IO signals are exposed to Charge Device Model (CDM) type of stress during assembly. The CDM stress is assessed to 5-35V of discharge voltage. That CDM voltage is dependent of quality of equipment in assembly line and electrostatic protection level with air ionizers. The CDM voltage may correspond to 40 mA-300 mA of CDM discharge current, depending of voltage level and die size.

Some examples of the IC device 500 may utilize an area efficient layout of ESD diode, as described herein, for CDM protection in D2D IO. The area efficient layout style may be applied but not limited to diodes connected to at least two pads (e.g., such as PAD1 and PAD2 referred to elsewhere herein). The ESD diodes in D2D IOs may be laid out in stripe geometry, because there is no latchup requirement. The strap diffusions of diodes at PAD1 and PAD2 can be shared, because the HBM test is not required for D2D IOs. The shared-strap diode-layout-style may be applied to one-finger diode or multi-finger diodes (e.g., FIG. 4 shows a layout of a two-finger stripe diode).

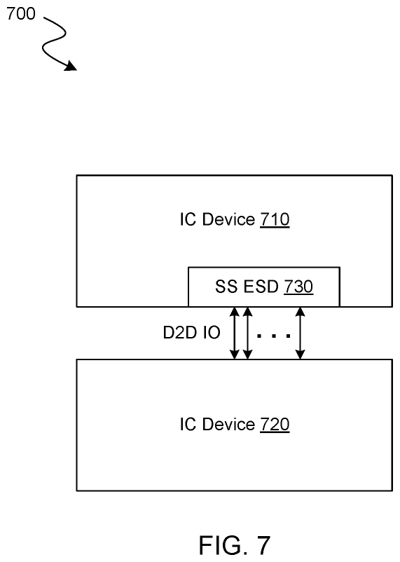

FIG. 7 shows a block diagram of an example of a system 700 that includes two IC devices 710, 720 with D2D IO signals therebetween, although other examples of the system 700 may include more than two IC devices. One or more of the IC devices (e.g., at least IC device 710) includes respective shared-stripe ESD (SS ESD) protection circuits 730 as described herein for two or more of the D2D IO signals.

In some examples, the ESD protection circuits 730 may comprise a plurality of P-diodes and a plurality of N-diodes arranged in a stripe geometry, a p-tap anode stripe of the SS ESD protection circuit 730 shared between a first P-diode and a second P-diode of the SS ESD protection circuit 730, and a n-tap cathode stripe of the SS ESD protection circuit 730 shared between a first N-diode and a second N-diode of the SS ESD protection circuit 730. In some examples, the SS ESD protection circuit 730 may provide protection for a signal from a static charge stored in the IC device 710 itself (e.g., CDM). For example, the SS ESD protection circuit 730 may provide protection for the signal from a discharge voltage of between five volts and thirty five volts.

In some examples, an anode of the first P-diode and a cathode of the first N-diode are coupled to a first pad, and an anode of the second P-diode and a cathode of the second N-diode are coupled to a second pad, and the SS ESD protection circuit may further include a first strap diffusion of the first P-diode and the first N-diode at the first pad shared with a second strap diffusion of the second P-diode and the second N-diode at the second pad. In some examples, the shared first and second strap diffusions are arranged in a one-finger layout. In some examples, the shared first and second strap diffusions are arranged in a multi-finger layout.

In some examples, a physical layout of the SS ESD protection circuit may comprise a first metallization structure for a first pad on a first layer with connections under the first metallization structure on another layer to an anode of a first P-diode and a cathode of a first N-diode, a second metallization structure for a second pad on the first layer with connections under the second metallization structure on another layer to an anode of a second P-diode and a cathode of a second N-diode, a third metallization structure for a positive voltage source on the first layer between and immediately adjacent to the first and second metallization structures and with connections under the third metallization structure on another layer to respective cathodes of the first and second P-diodes, and a fourth metallization structure for a reference voltage source on the first layer aligned with the third metallization structure and between and immediately adjacent to the first and second metallization structures and with connections under the fourth metallization structure on another layer to respective anodes of the first and second N-diodes. For example, the first layer corresponds to an external layer of one of the one or more IC devices. In some examples, the physical layout of the SS ESD protection circuit may further comprise a multi-finger diode arrangement that includes a fifth metallization structure for the first pad on a first layer immediately adjacent to and on an opposite side of the second metallization structure with respect to the third metallization structure, a sixth metallization structure for the second pad on the first layer, and a seventh metallization structure for the positive voltage source on the first layer between and immediately adjacent to the fifth and sixth metallization structures.

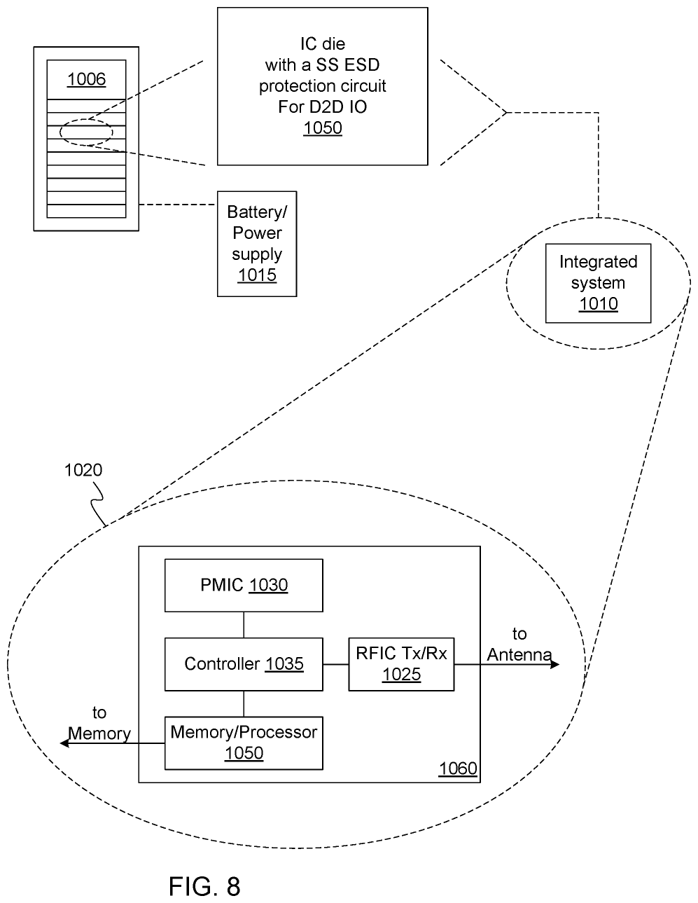

FIG. 8 illustrates a diagram of an example data server machine 1006 employing an IC device 1050 with a SS ESD protection circuit for D2D IO as described herein, in accordance with some examples. Server machine 1006 may be any commercial server, for example, including any number of high-performance computing platforms disposed within a rack and networked together for electronic data processing, that in the exemplary example includes one or more devices 1050 having one or more SS ESD protection circuits for D2D IO.

Also as shown, server machine 1006 includes a battery and/or power supply 1015 to provide power to devices 1050, and to provide, in some examples, power delivery functions such as power regulation. Devices 1050 may be deployed as part of a package-level integrated system 1010. Integrated system 1010 is further illustrated in the expanded view 1020. In the exemplary example, devices 1050 (labeled “Memory/Processor”) includes at least one memory chip (e.g., RAM), and/or at least one processor chip (e.g., a microprocessor, a multi-core microprocessor, or graphics processor, or the like) having the characteristics discussed herein. In an example, device 1050 is a microprocessor including a cache memory. As shown, device 1050 may be a multi-chip module employing one or more IC devices with one or more SS ESD protection circuits for D2D IO, as discussed herein. Device 1050 may be further coupled to (e.g., communicatively coupled to) a board, an interposer, or a substrate 1060 along with, one or more of a power management IC (PMIC) 1030, RF (wireless) IC (RFIC) 1025, including a wideband RF (wireless) transmitter and/or receiver (TX/RX) (e.g., including a digital baseband and an analog front end module further comprises a power amplifier on a transmit path and a low noise amplifier on a receive path), and a controller 1035 thereof. In some examples, RFIC 1025, PMIC 1030, controller 1035, and device 1050 include IC devices having a SS ESD protection circuits for D2D IO on substrate 1060 in a multi-chip module.

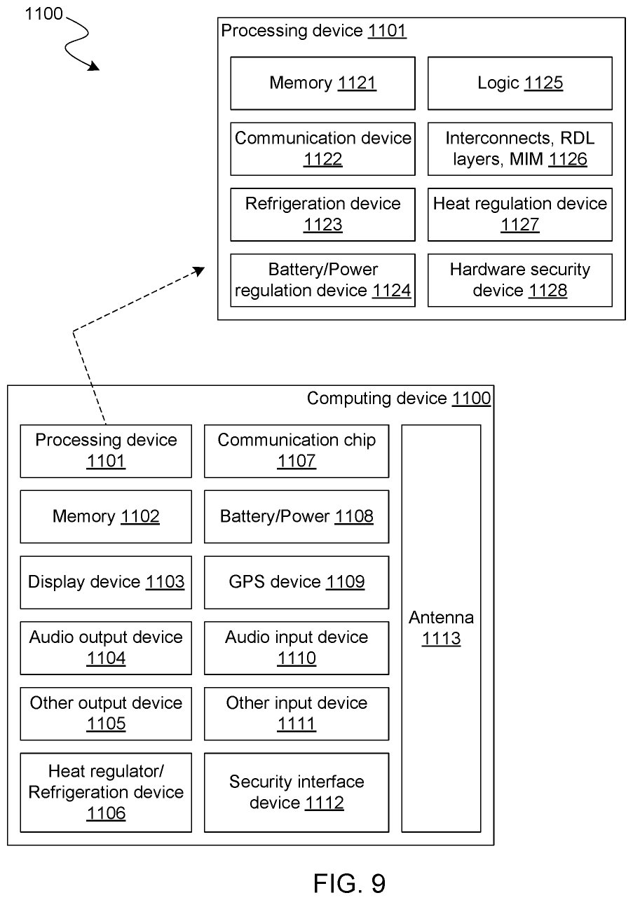

FIG. 9 is a block diagram of an example computing device 1100, in accordance with some examples. For example, one or more components of computing device 1100 may include any of the devices or structures discussed herein. A number of components are illustrated in FIG. 9 as being included in computing device 1100, but any one or more of these components may be omitted or duplicated, as suitable for the application. In some examples, some or all of the components included in computing device 1100 may be attached to one or more printed circuit boards (e.g., a motherboard). In some examples, various ones of these components may be fabricated onto a single system-on-a-chip (SoC) die. Additionally, in various examples, computing device 1100 may not include one or more of the components illustrated in FIG. 9, but computing device 1100 may include interface circuitry for coupling to the one or more components. For example, computing device 1100 may not include a display device 1103, but may include display device interface circuitry (e.g., a connector and driver circuitry) to which display device 1103 may be coupled. In another set of examples, computing device 1100 may not include an audio output device 1104, other output device 1105, global positioning system (GPS) device 1109, audio input device 1110, or other input device 1111, but may include audio output device interface circuitry, other output device interface circuitry, GPS device interface circuitry, audio input device interface circuitry, audio input device interface circuitry, to which audio output device 1104, other output device 1105, GPS device 1109, audio input device 1110, or other input device 1111 may be coupled.

Computing device 1100 may include a processing device 1101 (e.g., one or more processing devices). As used herein, the term “processing device” or “processor” indicates a device that processes electronic data from registers and/or memory to transform that electronic data into other electronic data that may be stored in registers and/or memory. Processing device 1101 may include a memory 1121, a communication device 1122, a refrigeration device 1123, a battery/power regulation device 1124, logic 1125, interconnects 1126 (i.e., optionally including redistribution layers (RDL) or metal-insulator-metal (MIM) devices), a heat regulation device 1127, and a hardware security device 1128.

Processing device 1101 may include one or more digital signal processors (DSPs), application-specific ICs (ASICs), central processing units (CPUs), graphics processing units (GPUs), cryptoprocessors (specialized processors that execute cryptographic algorithms within hardware), server processors, or any other suitable processing devices.

Computing device 1100 may include a memory 1102, that may itself include one or more memory devices such as volatile memory (e.g., dynamic random-access memory (DRAM)), nonvolatile memory (e.g., read-only memory (ROM)), flash memory, solid state memory, and/or a hard drive. In some examples, memory 1102 includes memory that shares a die with processing device 1101. This memory may be used as cache memory and may include embedded dynamic random-access memory (eDRAM) or spin transfer torque magnetic random-access memory (STT-M RAM).

Computing device 1100 may include a heat regulation/refrigeration device 1106. Heat regulation/refrigeration device 1106 may maintain processing device 1101 (and/or other components of computing device 1100) at a predetermined low temperature during operation. This predetermined low temperature may be any temperature discussed herein.

In some examples, computing device 1100 may include a communication chip 1107 (e.g., one or more communication chips). For example, the communication chip 1107 may be configured for managing wireless communications for the transfer of data to and from computing device 1100. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some examples they might not.

Communication chip 1107 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultramobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, that is a certification mark for products that pass conformity and interoperability tests for the IEEE 802.16 standards. Communication chip 1107 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. Communication chip 1107 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). Communication chip 1107 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. Communication chip 1107 may operate in accordance with other wireless protocols in other examples. Computing device 1100 may include an antenna 1113 to facilitate wireless communications and/or to receive other wireless communications (such as AM or FM radio transmissions).

In some examples, communication chip 1107 may manage wired communications, such as electrical, optical, or any other suitable communication protocols (e.g., the Ethernet). As noted above, communication chip 1107 may include multiple communication chips. For instance, a first communication chip 1107 may be dedicated to shorter-range wireless communications such as Wi-Fi or Bluetooth, and a second communication chip 1107 may be dedicated to longer-range wireless communications such as GPS, EDGE, GPRS, CDMA, WiMAX, LTE, EV-DO, or others. In some examples, a first communication chip 1107 may be dedicated to wireless communications, and a second communication chip 1107 may be dedicated to wired communications.

Computing device 1100 may include battery/power circuitry 1108. Battery/power circuitry 1108 may include one or more energy storage devices (e.g., batteries or capacitors) and/or circuitry for coupling components of computing device 1100 to an energy source separate from computing device 1100 (e.g., AC line power).

Computing device 1100 may include a display device 1103 (or corresponding interface circuitry, as discussed above). Display device 1103 may include any visual indicators, such as a heads-up display, a computer monitor, a projector, a touchscreen display, a liquid crystal display (LCD), a light-emitting diode display, or a flat panel display, for example.

Computing device 1100 may include an audio output device 1104 (or corresponding interface circuitry, as discussed above). Audio output device 1104 may include any device that generates an audible indicator, such as speakers, headsets, or earbuds, for example.

Computing device 1100 may include an audio input device 1110 (or corresponding interface circuitry, as discussed above). Audio input device 1110 may include any device that generates a signal representative of a sound, such as microphones, microphone arrays, or digital instruments (e.g., instruments having a musical instrument digital interface (MIDI) output).

Computing device 1100 may include a GPS device 1109 (or corresponding interface circuitry, as discussed above). GPS device 1109 may be in communication with a satellite-based system and may receive a location of computing device 1100, as known in the art.

Computing device 1100 may include other output device 1105 (or corresponding interface circuitry, as discussed above). Examples of the other output device 1105 may include an audio codec, a video codec, a printer, a wired or wireless transmitter for providing information to other devices, or an additional storage device.

Computing device 1100 may include other input device 1111 (or corresponding interface circuitry, as discussed above). Examples of the other input device 1111 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

Computing device 1100 may include a security interface device 1112. Security interface device 1112 may include any device that provides security measures for computing device 1100 such as intrusion detection, biometric validation, security encode or decode, access list management, malware detection, or spyware detection.

Computing device 1100, or a subset of its components, may have any appropriate form factor, such as a hand-held or mobile computing device (e.g., a cell phone, a smart phone, a mobile internet device, a music player, a tablet computer, a laptop computer, a netbook computer, a personal digital assistant (PDA), an ultramobile personal computer, etc.), a desktop computing device, a server or other networked computing component, a printer, a scanner, a monitor, a set-top box, an entertainment control unit, a vehicle control unit, a digital camera, a digital video recorder, or a wearable computing device.

The subject matter of the present description is not necessarily limited to specific applications illustrated in FIGS. 1-9. The subject matter may be applied to other transistor applications, as well as any appropriate manufacturing application, as will be understood to those skilled in the art.

The following examples pertain to further examples, and specifics in the examples may be used anywhere in one or more examples.

Example 1 includes an integrated circuit (IC) device, comprising an electrostatic discharge (ESD) protection circuit comprising a plurality of P+/N-well diodes (P-diodes) and a plurality of N+/P-well (N-diodes) arranged in a stripe geometry, a p-tap anode stripe of the ESD protection circuit shared between a first P-diode and a second P-diode of the ESD protection circuit, and a n-tap cathode stripe of the ESD protection circuit shared between a first N-diode and a second N-diode of the ESD protection circuit.

Example 2 includes the IC device of Example 1, wherein the ESD protection circuit provides protection for a signal from a static charge stored in the IC itself.

Example 3 includes the IC device of Example 2, wherein the ESD protection circuit provides protection for the signal from a discharge voltage of between five volts and thirty five volts.

Example 4 includes the IC device of any of Examples 2 to 3, wherein the signal comprises a die-to-die input/output signal.

Example 5 includes the IC device of any of Examples 1 to 4, wherein an anode of the first P-diode and a cathode of the first N-diode are coupled to a first pad, and wherein an anode of the second P-diode and a cathode of the second N-diode are coupled to a second pad, the IC device further comprising a first strap diffusion of the first P-diode and the first N-diode at the first pad shared with a second strap diffusion of the second P-diode and the second N-diode at the second pad.

Example 6 includes the IC device of Example 5, wherein the shared first and second strap diffusions are arranged in a one-finger layout.

Example 7 includes the IC device of Example 5, wherein the shared first and second strap diffusions are arranged in a multi-finger layout.

Example 8 includes an apparatus, comprising a first P+/N-well diode (P-diode), a first N+/P-well diode (N-diode), a second P-diode, and a second N-diode, a first metallization structure for a first pad on a first layer with connections under the first metallization structure on another layer to an anode of the first P-diode and a cathode of the first N-diode, a second metallization structure for a second pad on the first layer with connections under the second metallization structure on another layer to an anode of the second P-diode and a cathode of the second N-diode, a third metallization structure for a positive voltage source on the first layer between and immediately adjacent to the first and second metallization structures and with connections under the third metallization structure on another layer to respective cathodes of the first and second P-diodes, and a fourth metallization structure for a reference voltage source on the first layer aligned with the third metallization structure and between and immediately adjacent to the first and second metallization structures and with connections under the fourth metallization structure on another layer to respective anodes of the first and second N-diodes.

Example 9 includes the apparatus of Example 8, wherein the first and second P-diodes and the first and second N-diodes are arranged in a stripe geometry.

Example 10 includes the apparatus of any of Examples 8 to 9, wherein the first layer corresponds to an external layer of an integrated circuit (IC) device.

Example 11 includes the apparatus of any of Examples 8 to 10, wherein the first and second P-diodes and the first and second N-diodes are to provide electrostatic discharge protection for a die-to-die input/output signal.

Example 12 includes the apparatus of any of Examples 8 to 11, further comprising a multi-finger diode arrangement that includes a fifth metallization structure for the first pad on a first layer immediately adjacent to and on an opposite side of the second metallization structure with respect to the third metallization structure, a sixth metallization structure for the second pad on the first layer, and a seventh metallization structure for the positive voltage source on the first layer between and immediately adjacent to the fifth and sixth metallization structures.

Example 13 includes a system, comprising two or more integrated circuit (IC) devices with die-to-die (D2D) input/output (IO) signals therebetween, one or more of the IC devices including respective electrostatic discharge (ESD) protection circuits for two or more of the D2D IO signals, the ESD protection circuits comprising a plurality of P+/N-well diodes (P-diodes) and a plurality of N+/P-well (N-diodes) arranged in a stripe geometry, a p-tap anode stripe of the ESD protection circuit shared between a first P-diode and a second P-diode of the ESD protection circuit, and a n-tap cathode stripe of the ESD protection circuit shared between a first N-diode and a second N-diode of the ESD protection circuit.

Example 14 includes the system of Example 13, wherein the ESD protection circuit provides protection for a signal from a static charge stored in the IC itself.

Example 15 includes the system of Example 14, wherein the ESD protection circuit provides protection for the signal from a discharge voltage of between five volts and thirty five volts.

Example 16 includes the system of any of Examples 14 to 15, wherein the signal comprises a die-to-die input/output signal.

Example 17 includes the system of any of Examples 13 to 16, wherein an anode of the first P-diode and a cathode of the first N-diode are coupled to a first pad, and wherein an anode of the second P-diode and a cathode of the second N-diode are coupled to a second pad, the IC device further comprising a first strap diffusion of the first P-diode and the first N-diode at the first pad shared with a second strap diffusion of the second P-diode and the second N-diode at the second pad.

Example 18 includes the system of Example 17, wherein the shared first and second strap diffusions are arranged in a one-finger layout.

Example 19 includes the system of Example 17, wherein the shared first and second strap diffusions are arranged in a multi-finger layout.

Example 20 includes the system of any of Examples 13 to 19, wherein a physical layout of the ESD protection circuit comprises a first metallization structure for a first pad on a first layer with connections under the first metallization structure on another layer to an anode of a first P-diode and a cathode of a first N-diode, a second metallization structure for a second pad on the first layer with connections under the second metallization structure on another layer to an anode of a second P-diode and a cathode of a second N-diode, a third metallization structure for a positive voltage source on the first layer between and immediately adjacent to the first and second metallization structures and with connections under the third metallization structure on another layer to respective cathodes of the first and second P-diodes, and a fourth metallization structure for a reference voltage source on the first layer aligned with the third metallization structure and between and immediately adjacent to the first and second metallization structures and with connections under the fourth metallization structure on another layer to respective anodes of the first and second N-diodes.

Example 21 includes the system of Example 20, wherein the first layer corresponds to an external layer of one of the one or more IC devices.

Example 22 includes the system of any of Examples 20 to 21, further comprising a multi-finger diode arrangement that includes a fifth metallization structure for the first pad on a first layer immediately adjacent to and on an opposite side of the second metallization structure with respect to the third metallization structure, a sixth metallization structure for the second pad on the first layer, and a seventh metallization structure for the positive voltage source on the first layer between and immediately adjacent to the fifth and sixth metallization structures.

Example 23 includes a method, comprising forming a first P+/N-well diode (P-diode), a first N+/P-well diode (N-diode), a second P-diode, and a second N-diode on a substrate, forming a first metallization structure for a first pad on a first layer of the substrate with connections under the first metallization structure on another layer of the substrate to an anode of the first P-diode and a cathode of the first N-diode, forming a second metallization structure for a second pad on the first layer of the substrate with connections under the second metallization structure on another layer of the substrate to an anode of the second P-diode and a cathode of the second N-diode, forming a third metallization structure for a positive voltage source on the first layer of the substrate between and immediately adjacent to the first and second metallization structures and with connections under the third metallization structure on another layer of the substrate to respective cathodes of the first and second P-diodes, and forming a fourth metallization structure for a reference voltage source on the first layer of the substrate aligned with the third metallization structure and between and immediately adjacent to the first and second metallization structures and with connections under the fourth metallization structure on another layer to respective anodes of the first and second N-diodes.

Example 24 includes the method of Example 23, wherein the first and second P-diodes and the first and second N-diodes are arranged in a stripe geometry.

Example 25 includes the method of any of Examples 23 to 24, wherein the first layer of the substrate corresponds to an external layer of an integrated circuit (IC) device.

Example 26 includes the method of any of Examples 23 to 25, wherein the first and second P-diodes and the first and second N-diodes are to provide electrostatic discharge protection for a die-to-die input/output signal.

Example 27 includes the method of any of Examples 23 to 26, further comprising forming a multi-finger diode arrangement including forming a fifth metallization structure for the first pad on a first layer of the substrate immediately adjacent to and on an opposite side of the second metallization structure with respect to the third metallization structure, forming a sixth metallization structure for the second pad on the first layer of the substrate, and forming a seventh metallization structure for the positive voltage source on the first layer of the substrate between and immediately adjacent to the fifth and sixth metallization structures.

Example 28 includes an apparatus, comprising means for forming a first P+/N-well diode (P-diode), a first N+/P-well diode (N-diode), a second P-diode, and a second N-diode on a substrate, means for forming a first metallization structure for a first pad on a first layer of the substrate with connections under the first metallization structure on another layer of the substrate to an anode of the first P-diode and a cathode of the first N-diode, means for forming a second metallization structure for a second pad on the first layer of the substrate with connections under the second metallization structure on another layer of the substrate to an anode of the second P-diode and a cathode of the second N-diode, means for forming a third metallization structure for a positive voltage source on the first layer of the substrate between and immediately adjacent to the first and second metallization structures and with connections under the third metallization structure on another layer of the substrate to respective cathodes of the first and second P-diodes, and means for forming a fourth metallization structure for a reference voltage source on the first layer of the substrate aligned with the third metallization structure and between and immediately adjacent to the first and second metallization structures and with connections under the fourth metallization structure on another layer to respective anodes of the first and second N-diodes.

Example 29 includes the apparatus of Example 28, wherein the first and second P-diodes and the first and second N-diodes are arranged in a stripe geometry.

Example 30 includes the apparatus of any of Examples 28 to 29, wherein the first layer of the substrate corresponds to an external layer of an integrated circuit (IC) device.

Example 31 includes the apparatus of any of Examples 28 to 30, wherein the first and second P-diodes and the first and second N-diodes are to provide electrostatic discharge protection for a die-to-die input/output signal.

Example 32 includes the apparatus of any of Examples 28 to 31, further comprising means for forming a multi-finger diode arrangement including means for forming a fifth metallization structure for the first pad on a first layer of the substrate immediately adjacent to and on an opposite side of the second metallization structure with respect to the third metallization structure, means for forming a sixth metallization structure for the second pad on the first layer of the substrate, and means for forming a seventh metallization structure for the positive voltage source on the first layer of the substrate between and immediately adjacent to the fifth and sixth metallization structures.

The disclosure can be practiced with modification and alteration, and the scope of the appended claims is not limited to the examples so described. For example, the above examples may include specific combinations of features. However, the above examples are not limiting in this regard and, in various implementations, the above examples may include the undertaking only a subset of such features, undertaking a different order of such features, undertaking a different combination of such features, and/or undertaking additional features than those features explicitly listed. The scope of the patent rights should, therefore, be determined with reference to the appended claims, along with the full scope of equivalents to which such claims are entitled.

We claim:

1. An integrated circuit (IC) device, comprising:
an electrostatic discharge (ESD) protection circuit comprising a plurality of P+/N-well diodes (P-diodes) and a plurality of N+/P-well (N-diodes) arranged in a stripe geometry;
a p-tap anode stripe of the ESD protection circuit shared between a first P-diode and a second P-diode of the ESD protection circuit; and
a n-tap cathode stripe of the ESD protection circuit shared between a first N-diode and a second N-diode of the ESD protection circuit.

2. The IC device of claim 1, wherein the ESD protection circuit provides protection for a signal from a static charge stored in the IC itself.

3. The IC device of claim 2, wherein the ESD protection circuit provides protection for the signal from a discharge voltage of between five volts and thirty five volts.

4. The IC device of claim 2, wherein the signal comprises a die-to-die input/output signal.

5. The IC device of claim 1, wherein an anode of the first P-diode and a cathode of the first N-diode are coupled to a first pad, and wherein an anode of the second P-diode and a cathode of the second N-diode are coupled to a second pad, the IC device further comprising:
a first strap diffusion of the first P-diode and the first N-diode at the first pad shared with a second strap diffusion of the second P-diode and the second N-diode at the second pad.

6. The IC device of claim 5, wherein the shared first and second strap diffusions are arranged in a one-finger layout.

7. The IC device of claim 5, wherein the shared first and second strap diffusions are arranged in a multi-finger layout.

8. An apparatus, comprising:
a first P+/N-well diode (P-diode), a first N+/P-well diode (N-diode), a second P-diode, and a second N-diode;
a first metallization structure for a first pad on a first layer with connections under the first metallization structure on another layer to an anode of the first P-diode and a cathode of the first N-diode;
a second metallization structure for a second pad on the first layer with connections under the second metallization structure on another layer to an anode of the second P-diode and a cathode of the second N-diode;
a third metallization structure for a positive voltage source on the first layer between and immediately adjacent to the first and second metallization structures and with connections under the third metallization structure on another layer to respective cathodes of the first and second P-diodes; and
a fourth metallization structure for a reference voltage source on the first layer aligned with the third metallization structure and between and immediately adjacent to the first and second metallization structures and with connections under the fourth metallization structure on another layer to respective anodes of the first and second N-diodes.

9. The apparatus of claim 8, wherein the first and second P-diodes and the first and second N-diodes are arranged in a stripe geometry.

10. The apparatus of claim 8, wherein the first layer corresponds to an external layer of an integrated circuit (IC) device.

11. The apparatus of claim 8, wherein the first and second P-diodes and the first and second N-diodes are to provide electrostatic discharge protection for a die-to-die input/output signal.

12. The apparatus of claim 8, further comprising a multi-finger diode arrangement that includes:
a fifth metallization structure for the first pad on a first layer immediately adjacent to and on an opposite side of the second metallization structure with respect to the third metallization structure;
a sixth metallization structure for the second pad on the first layer; and
a seventh metallization structure for the positive voltage source on the first layer between and immediately adjacent to the fifth and sixth metallization structures.

13. A system, comprising two or more integrated circuit (IC) devices with die-to-die (D2D) input/output (IO) signals therebetween, one or more of the IC devices including respective electrostatic discharge (ESD) protection circuits for two or more of the D2D IO signals, the ESD protection circuits comprising:
a plurality of P+/N-well diodes (P-diodes) and a plurality of N+/P-well (N-diodes) arranged in a stripe geometry;
a p-tap anode stripe of the ESD protection circuit shared between a first P-diode and a second P-diode of the ESD protection circuit; and
a n-tap cathode stripe of the ESD protection circuit shared between a first N-diode and a second N-diode of the ESD protection circuit.

14. The system of claim 13, wherein the ESD protection circuit provides protection for a signal from a static charge stored in the IC itself.

15. The system of claim 14, wherein the ESD protection circuit provides protection for the signal from a discharge voltage of between five volts and thirty five volts.

16. The system of claim 14, wherein the signal comprises a die-to-die input/output signal.

17. The system of claim 13, wherein an anode of the first P-diode and a cathode of the first N-diode are coupled to a first pad, and wherein an anode of the second P-diode and a cathode of the second N-diode are coupled to a second pad, the IC device further comprising:
a first strap diffusion of the first P-diode and the first N-diode at the first pad shared with a second strap diffusion of the second P-diode and the second N-diode at the second pad.

18. The system of claim 17, wherein the shared first and second strap diffusions are arranged in a one-finger layout.

19. The system of claim 17, wherein the shared first and second strap diffusions are arranged in a multi-finger layout.

20. The system of claim 13, wherein a physical layout of the ESD protection circuit comprises:
a first metallization structure for a first pad on a first layer with connections under the first metallization structure on another layer to an anode of a first P-diode and a cathode of a first N-diode;
a second metallization structure for a second pad on the first layer with connections under the second metallization structure on another layer to an anode of a second P-diode and a cathode of a second N-diode;
a third metallization structure for a positive voltage source on the first layer between and immediately adjacent to the first and second metallization structures and with connections under the third metallization structure on another layer to respective cathodes of the first and second P-diodes; and
a fourth metallization structure for a reference voltage source on the first layer aligned with the third metallization structure and between and immediately adjacent to the first and second metallization structures and with connections under the fourth metallization structure on another layer to respective anodes of the first and second N-diodes.
